(19) United States
(12) Patent Application Publication
(10) Pub. No.: US 2005/0048205 A1
(43) Pub. Date: Mar. 3, 2005

(54) Method of producing thin film or powder array using liquid source misted chemical deposition process

(75) Inventors: Seong-Ihl Woo, Seoul (KR); Ki-Woong Kim, Seoul (KR)

Correspondence Address: Jonathan O. Owens;HAVERSTOCK & OWENS LLP, 162 North Wolfe Road, Sunnyvale, CA, 94086, US

(73) Assignee: Korea Advance Institute of Science and Technology

(21) Appl. No.: 10/852,792

(22) Filed: May 24, 2004

(30) Foreign Application Priority Data
Aug. 29, 2003 (KR) 10-2003-0060391

(51) Int. Cl. C23C 16/00

(52) U.S. Cl. 427/248.1; 427/901

(57) ABSTRACT

The present invention concerns a method of providing a wet deposition process with a shutter driven in one axis direction in order to produce a thin film or powder array various in composition on a wafer or in a reactor having apertures as many as the number of sample to be produced. A material having various compositions is transferred to an area predetermined by means of a mask on the wafer to form an array having minimum 16 to about 20000 different compositions by mixture or reaction of at least two or more materials to a minimum in a liquid state. By the process, it is possible to develop materials for various use, e.g., ferroelectrics and inorganic material including fluorescencers, organic polymers, organic metals, ionic solids and metal alloys, more efficiently than by the current experiment. The invention also comprises a method of characteristic analysis of the aforementioned array within a short time, in addition to development of the array having aforementioned various compositions.

### BACKGROUND OF THE INVENTION

1. Technical Field

The invention relates to a method of producing a thin film or a powder array various in composition in a predetermined area of a substrate on which a mask is placed or of a reactor with apertures as many as the number of samples by means of a wet deposition process such as a liquid source misted chemical deposition process, and also relates to efficiently implementing development of various materials and catalysts by means of characteristic analysis.

2. Description of the Prior Art

Newly discovered materials having new physical and chemical properties have contributed to creating new and useful industry and raising the level of human living. One example thereof is the single crystal semiconductor material discovered 40 years ago that initiated development of the current electronics industry.

Much effort has been made to discover and optimize new materials, e.g., superconductors, zeolite, magnetic materials, fluorescencers, dielectrics/ferroelectrics, catalysts for olefin polymerization, catalysts for upgrading heavy oil, catalysts for eliminating nitrogen oxides, etc. Although chemical experiment has been widely carried out for synthesizing many materials, however, no general rule has been found that can be predicted by a composition and structure of a material and a reaction path of solid compounds. This results in continued research of high cost and low effectiveness for developing new materials of the multicomponent system where synthesis and analysis of a new compound is based on existing knowledge and principles. For example, if the target is about 100 elements on the periodic table that can make a composition having a 3-composition system to 6-(or more) composition system, the limit of the search range through existing experiments is more apparent. Because of the aforementioned reason, there is a need to extend the research range to that not searched for with the existing experiments by means of more efficient and economical approach for developing new materials having useful features.

One example is the antibody system that exists in a human body for analyzing 10¹² antibody molecules for several weeks in order to find an antibody to be combined definitely with external viruses. It should be noted that the enormous number of target molecules are created and searched in a body at one time, and this is now efficiently applied to development of new medicine.

The focus of the research is to find a key matching to a lock having an unknown structure. The process for efficiently finding the key consists in making many keys different in structure and then searching for a proper key. That is, it is to implement a huge library (a collection of molecules) of more than 10¹⁴ peptides, nucleic acid and different small molecules on one substrate and then to carry out the finding process through characteristic analysis to which the aforementioned human antibody system is applied. On the assumption that this can be an efficient research process for developing a material where structure and composition affects features, researches for applying the process to the field of materials and catalysts have been carried out since 1995 in advanced countries, e.g., America and Japan. For example, an apparatus and a method for producing a substrate having a material array with various compositions are disclosed in PCT WO 96/11878 (1996) by P. G. Schultz et. al. The method consists in transferring composition elements composing a target material to a specified area on a substrate and producing the target material in order to form different materials. P. G. Schultz et. al. reported it was possible to develop various materials, e.g., inorganic materials, metal alloys, metal oxides (ceramic), etc. by the method. The symyx Co. built a library (an aggregate of materials) through a multi-target sputtering process, using a mask or shutter and the like driven in a horizontal or longitudinal direction by means of a computer and applied the library efficiently to development of electronic materials, e.g., superconductors through various methods of analysis, as disclosed in U.S. Pat. No. 6,045,671 (2000) by X. D. Wu, Y. Wang, and I. Goldwasser, U.S. Pat. No. 6,004,617 (1999) by P. G. Schultz, X.-D. Xiang, and I. Goldwasser, and U.S. Pat. No. 5,985,356 (1999) by P. G. Schultz, X.-D. Xiang, and I. Goldwasser.

The American team led by Dr. Xiang and the Japanese team led by professor Koinuma disclosed a method of producing a thin film array of metal oxide having various compositions on a substrate of one in² by means of a pulsed laser deposition process with a shutter driven in a horizontal or longitudinal axis direction, and then of characteristic-analyzing the array {X.-D. Xiang et. al, science, 268, 1738 (1995), H. Koinuma et. al., Jpn. J. Appl. Phys., 41, L149 (2002)}. Particularly in case of barium-strontium-titanate {(Ba,Sr)TiO₃ (BST)} that is a main material of a DRAM capacitor that has widely been studied, the process consists in producing a library various in the ratio of Ba/Sr on the whole substrate in the x-axis direction while repeating a process that BaTiO₃ is deposited when the shutter moves in the x-axis direction and SrTiO₃ is deposited when it moves in an opposite direction, using two targets of BaTiO₃ and SrTiO₃, and then finding a best dielectric material, using an optic instrument. In particular, Takeuchi et.al. announced that, when Ba/Sr=0.35/0.65, the material has the largest dielectric constant and has a physical characteristic change from paraelectricity to ferroelectricity in a specific composition {I. Takeuchi et. al., Appl. Phys. Lett., 79, 4411 (2001), I. Takeuchi et. al., Appl. Phys. Lett., 76, 769 (2000)}.

The aforementioned combinatorial chemistry (combi-chem) process consists in forming a multi-layer made of various materials by means of a dry deposition process such as a laser-ablated deposition or sputtering process with various types of masks or a shutter moving in one axial direction by means of a stepping motor, and then producing a metal alloy and metal oxide array through a multi-step thermal treatment process. Since it is intended to obtain a uniform phase through diffusion between solid layers, the reaction itself between solids is very difficult and thermal treatment conditions are very tightened, resulting in difficult synthesis of a material having a uniform phase. In order to solve the problem, several research teams have carried out deposition at a high temperature equal to or higher than 400° C. in the deposition process to produce the aforementioned array by means of efficient mixture and diffusion during the deposition process. In this case, however, it is considered inefficient because there is a high possibility to cause problems with respect to energy consumption and problems in some appliances, especially the shutter driven in a vacuum chamber due to high temperature in the process.

Also, the aforementioned appliances can be used only for producing thin film arrays as semiconductor deposition appliances, cannot be used for producing powder arrays, and thus can be used disadvantageously only for inorganic materials.

In addition, it is not easy to improve quality of films because the size of particles deposited through wet deposition such as sol-gel coating and spin coating is equal to or larger than 20 microns in some cases.

### BRIEF SUMMARY OF THE INVENTION

The inventors attempted to solve the aforementioned prior art problems and devised a method of this invention. Accordingly it is an object of the invention to provide a method of producing a metal, metal oxide thin-film or powder array having a uniform phase more efficiently than by the prior art method, in that two or more types of metal precursor liquid are converted to droplets using an ultrasonic oscillator and then transferred onto a substrate or into a reactor having more than 100 apertures in order to achieve the conversion by means of mixture and reaction between liquids at an ambient temperature, not by means of prior art reaction and diffusion between solids.

It is another object of the invention to provide a method of producing an array having various compositions by applying a different amount of droplets to each place to implement a concentration gradient, using a shutter driven in the x-axis direction provided on the liquid source misted chemical deposition apparatus.

Also, it is still another object of the invention to provide a method of producing various thin films or powder arrays by directly producing metal precursor liquid which is a component of a material to be produced, in order to solve a problem that it is difficult to produce various test materials because each target must be purchased which is needed in processes for the conventional combinatorial chemistry, such as sputtering.

Accordingly, it is a key purpose of the invention to provide a method of producing various materials such as electron-inorganic materials, e.g., ferroelectrics, fluorescencers, materials for cathodes and anodes of direct methanol decomposition cells, anodic thin films for lithium secondary batteries, superconductors, etc. including environment-friendly catalysts such as a catalyst for eliminating nitrogen oxides by means of combinatorial chemistry using the liquid misted chemical deposition process.

### BRIEF DESCRIPTION OF THE DRAWINGS

The features and advantages of the present invention will become apparent from the following detailed description of preferred embodiments thereof illustrated with reference to the accompanying drawings, wherein:

FIG. 1 is a block diagram showing main parts of a liquid source misted chemical deposition apparatus;

FIG. 2 is a front sectional view showing a moving shutter and a stepping motor equipped on the liquid source misted chemical deposition apparatus;

FIG. 3 shows schematically a process for producing a thin film and a powder array using a liquid source misted chemical deposition process;

FIG. 4 shows a configuration of a produced array for combi-chem and a photograph of an actually produced thin film array of (Bi,La,Ce)₄Ti₃O₁₂;

FIG. 5 is a graph showing results of structure analysis of a thin film array of (Bi,La,Ce)₄Ti₃O₁₂;

FIG. 6 is a SEM photograph showing a thin film array of (Bi,La,Ce)₄Ti₃O₁₂;

FIG. 7 is an electric field-polarization curve of a thin film array of (Bi,La,Ce)₄Ti₃O₁₂ in an embodiment 1-1;

FIG. 8 is a graph showing measurement results of leakage current density and fatigability of a thin film array of (Bi,La,Ce)₄Ti₃O₁₂; and

FIG. 9 is a graph of electric field-polarization of a thin film array of (Bi,La,Ce)₄Ti₃O₁₂ in an embodiment 1-2.

### DETAILED DESCRIPTION OF THE PREFERRED EMBODIMENTS

Now the present invention will be described in detail with reference to the accompanying drawings.

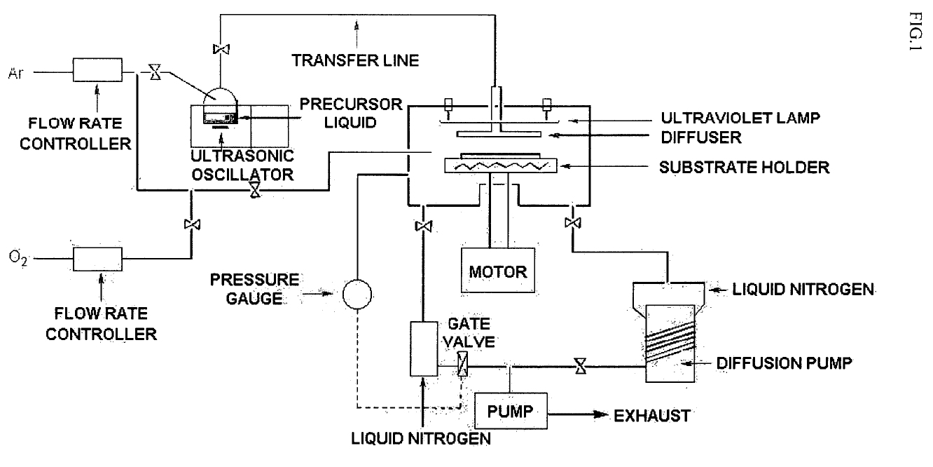

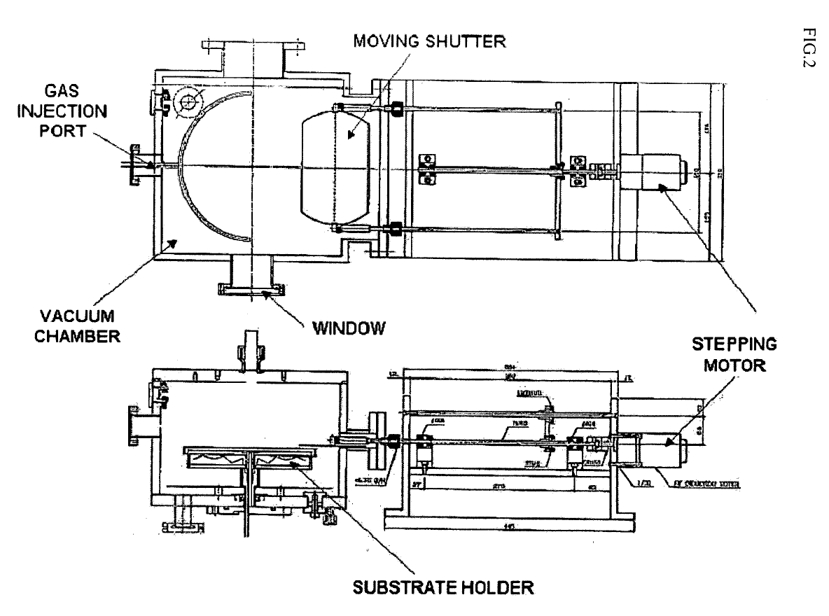

FIGS. 1 and 2 show schematically diagrams of a liquid source misted chemical deposition apparatus provided with a shutter driven into the x-axis direction. As previously described, the liquid source misted chemical deposition process consists in applying high frequency to a precursor liquid, in which various metal precursors are melt in a solvent to conform to a stoichiometric ratio, and then in transferring the resulting droplets to a substrate or into a micro reactor. When producing a sample array, vacuum (10⁻⁶ to 760 torrs) is kept, using a vacuum pump, and it is possible to use various types of gas, e.g., argon, nitrogen, oxygen, etc. The liquid source misted chemical deposition apparatus comprises: an ultrasonic oscillator (frequency: 1.65 MHz) for creating droplets; a stepping motor for driving a shutter in the x-axis direction, the shutter being provided on one side of a stainless or aluminum vacuum chamber; a controller for controlling the stepping motor; a transfer line for transferring the droplets; and a diffuser for uniformly distributing the droplets on a wafer having a diameter equal to or larger than 4 inches or into a micro reactor. After completing all the deposition process, an ultraviolet lamp is circularly equipped around the diffuser in order to dry the inside of the vacuum chamber, by injecting inert gas, e.g., argon or using a diffusing pump while keeping vacuum of the order of 10⁻⁶ torrs when producing an array of a test material sensitive to the air.

Now, the process will be described in steps.

<1> Producing Liquid

As a first step of the liquid source misted chemical deposition process, a target functional material and a catalyst are selected and a precursor related to the metal consisting of the material and the catalyst is then melt into a solvent in conformity to a stoichiometric ratio. This process has no specific restriction when using the precursor, unlike the chemical vapor deposition process that must have a high vaporization point at low temperature when using a precursor. The metal precursor that can be used in the liquid source misted chemical deposition process may be nitrate (—NO₃), acetate(—CH₃COO.2H₂O), carbonate (—CO₃), acetylacetonate (—CH₃COCHCOCH₃), 2-ethylhexanoate (—OOCCH(C₂H₅)C₄H₉), stearate ((O₂C₁₈H₃₅)₂) and alkoxide (—(OR)n, R=alkyl radical) or the mixture thereof. The solvent for dissolving the aforementioned precursors may be an organic solvent containing one to ten carbons, e.g., methanol, ethanol, propanol, isopropanol, butanol, 2-methoxyethanol, toluene, benzene, phenol, 2-ethylhexanoate, acetone, acetylacetonate, etc., or a polar solvent such as water.

<2> Producing a Combi-Chem Sample Array

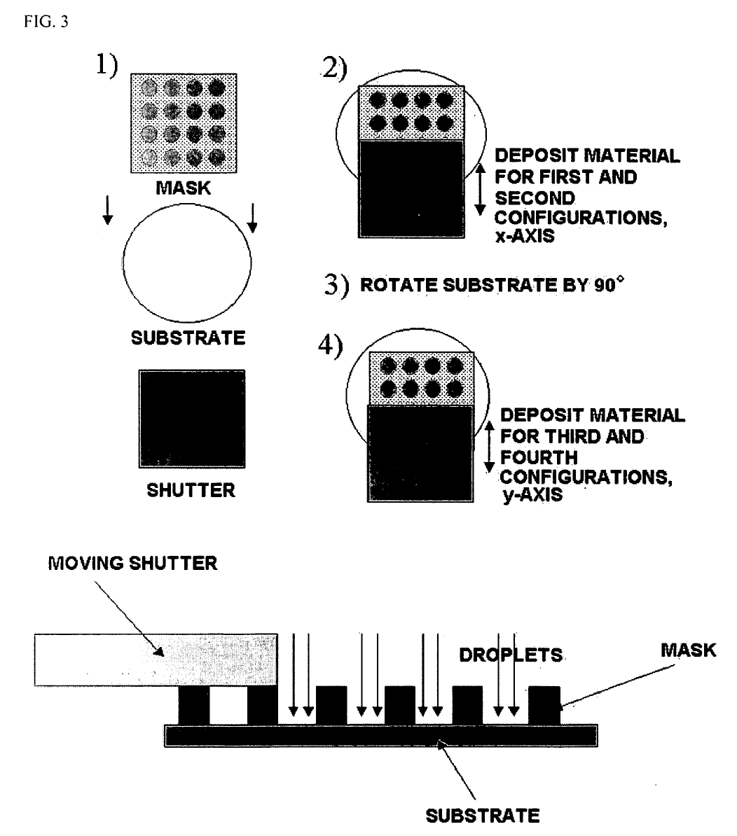

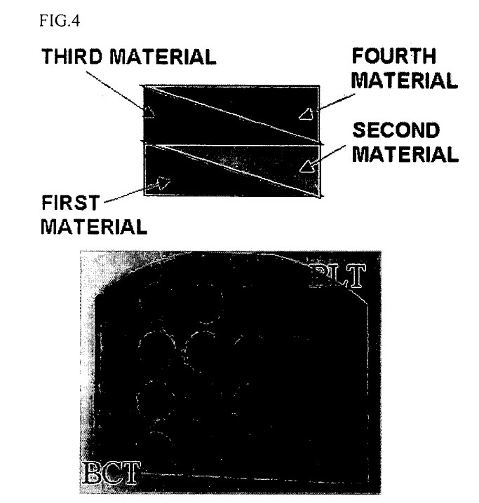

One of the two types of metal precursor liquid produced as such in the above step is selected, a small amount of which is then injected into a rector, and ultrasonic energy is subsequently applied to the selected liquid by means of an ultrasonic oscillator to produce micro droplets. While producing the droplets, the vacuum chamber is kept at 10⁻³ to 10⁻⁶ torrs, using a vacuum pump. Thereafter, in order to keep an inert atmosphere, an inert gas such as argon is injected to reach a pressure (10-700 torrs) in order to produce a sample material. At a pressure for deposition, the droplets containing the metal precursors produced in the reactor are transferred to the vacuum chamber, using the inert gas previously used as a transfer gas. The transferred droplets are moved to a wafer made of silicon or various materials, on which a mask with a specified area for deposition located on a substrate holder is placed and whose diameter is equal to or larger than 4 inches, or into a reactor having 100 or more apertures by means of the diffuser in the vacuum chamber. In this case, the flow rate of transfer gas is controlled by means of a mass flow rate controller to make the droplet flow be a laminar flow. While the droplets are transferred, the shutter is simultaneously driven into the x-axis direction by means of the stepping motor. A gradient in the amount of the droplets arriving along the axis is thereby achieved. After completing this process, the liquid is replaced by a second metal precursor liquid and the above process is then applied again to the replaced liquid. However, the direction for driving the shutter is opposite, so that it is possible to produce a sample array in which the amount of droplets arriving in one axis direction is uniform but which has a different composition, as shown in FIG. 3. By replacing the liquid by third and fourth metal precursor liquids in each step and repeating the above process after rotating the substrate holder by 90°, it is possible to produce minimum 16 to more than 1000 sample arrays different in composition. A schematic diagram of this process is shown in FIGS. 3 and 4.

After completing production of samples, the solvent is volatilized using an ultraviolet lamp in the vacuum chamber and then the powder or thin film sample array is taken out from the vacuum chamber, subject to a subsequent thermal treatment process, using a furnace or a rapid thermal annealing apparatus to produce a desired powder or thin film sample array. It is also possible to use various gases, e.g., oxygen or hydrogen, etc. as an atmosphere gas in the subsequent thermal treatment process.

Hereinafter, with the embodiments, the invention will be described in more detail. It will be apparent to those skilled in the art that the embodiments are intended to describe the invention in more detail, and the scope of the invention is not limited to the embodiments according to the subject of the invention.

Embodiment 1: Producing a Ferroelectric Thin Film Array

Embodiment 1-1: Producing a thin film array of (Bi,La,Ce)₄Ti₃O₁₂ (BLCT) (I)

Bismuth nitrate {Bi(NO₃)₃.6H₂O} that is a precursor of bismuth, lanthanum nitrate {La(NO₃)₃.6H₂O} and titanium isoproxide {Ti(O—ⁱC₃H₇)} that are precursors of lanthanum and titanium are used. These precursors are dissolved in 2-methoxyethanol (CH₃OCH₂CH₂OH) in conformity to the stoichiometric ratio (Bi:La:Ti=3.25:0.75:3) to produce a metal precursor liquid (A) for producing bismuth-lanthanum-titanate. With cerium nitrate (Ce(NO₃)₃.6H₂O) instead of lanthanum nitrate in the above liquid, a metal precursor liquid (B) for producing bismuth-cerium-titanate is produced with the same stoichiometric ratio. In this case, considering bismuth volatility in the thermal treatment process, about 20% is added more. First, liquid A is put into the reactor and high frequency is applied to the liquid A to produce droplets. As previously described, while the droplets arrives through the diffuser, the shutter is simultaneously driven into the x-axis direction and the liquid A is deposited. Subsequently, the liquid A is replaced by liquid B. For the liquid B, the above process is repeated and the shutter is driven into the opposite direction. Then, the substrate is rotated by 90° and the above process is applied again but for different deposition time to produce 14 samples different in composition as shown in Table 1. The sample array is taken out of the vacuum chamber after completing the deposition process, subject to thermal treatment for 5 hours at 400° C. and then subsequent thermal treatment at an oxygen atmosphere at 700° C. for one hour after raising the temperature in the furnace, in order to obtain a resultant thin film array. In this case, the heating-up speed was 7° C./min. The resultant thin film array is subject to microbeam X-ray diffraction analysis (XRD) and micrograph analysis with a scanning electron microscope (SEM) to observe the surface and the section thereof. By means of WDS, each sample is analyzed for its composition. Also a platinum top electrode whose diameter is 100 to 500 micrometers is deposited to each sample by sputtering to measure residual polarization and leakage current density that is one of ferroelectric features, and fatigability features. For XRD, Brukers AXS GADDS D8 Discover (microbeam X-ray diffraction instrument) having CuKa radiation operated at 40 kV and 40 mA is used. In the range of 15° to 60°, 2θ was recorded as 0.01° resolution. SEM was measured with Philips 533M. In addition, in order to measure electric features, it is made to have a structure of platinum (top electrode)/produced ferroelectric library/platinum (bottom electrode). With RT66A, an electric field-polarization curve was measured to observe the composition of the thin film having the ferroelectric feature.

TABLE 1
Composition of Thin Film Library of Bi_{3.25}LaxCe_{0.75-x}Ti₃O₁₂
In order of Bi/La/Ce (Bi_{3.25}LaxCe_{0.75-x}Ti₃O₁₂)

| | | | |
|---|---|---|---|
| 3.25/0.3/0.45 | 3.25/0.45/0.3 | 3.25/0.6/0.15 | 3.25/0.75/0 |
| 3.25/0.2/0.55 | 3.25/0.35/0.4 | 3.25/0.5/0.25 | 3.25/0.65/0.1 |
| 3.25/0.1/0.65 | 3.25/0.25/0.5 | 3.25/0.4/0.35 | 3.25/0.55/0.2 |
| 3.25/0/0.75 | 3.25/0.15/0.6 | 3.25/0.3/0.45 | 3.25/0.45/0.3 |

(The composition shown in Table 1 is based on chemical molecular formulae, and the parts with slash lines are compositions showing ferroelectric features.)

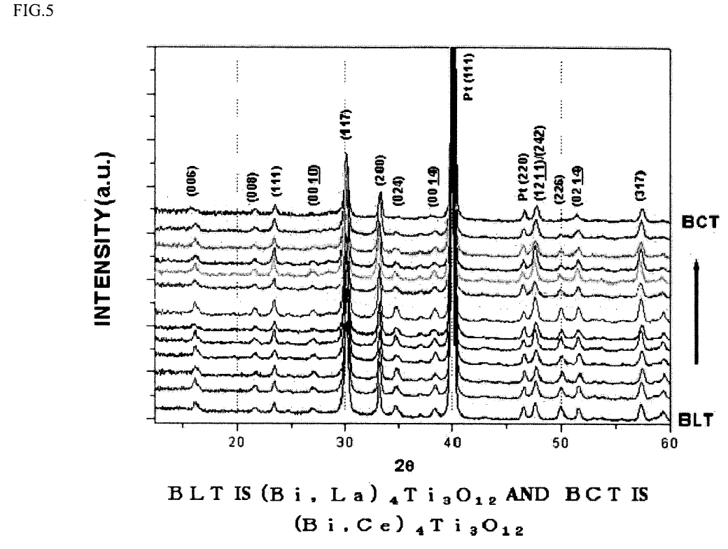

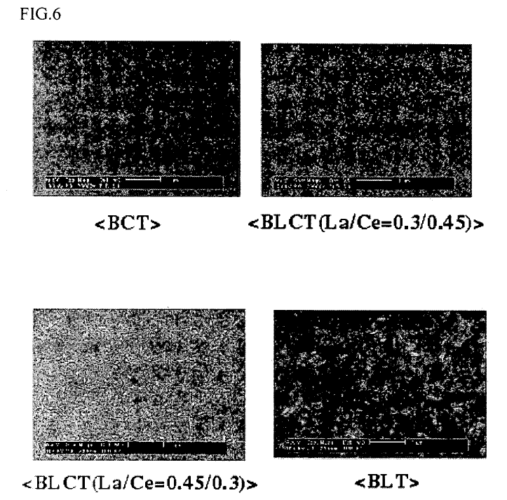

FIGS. 5 and 6 show results of XRD and surface analysis for the aforementioned library of bismuth layer structure. As shown in FIG. 6, it is seen that a thin film array having a uniform phase in which impurity phase such as Bi₂O₃ (2θ=28°) did not exist is obtained because of volatized bismuth. It is easily observed that, as the amount of lanthanum increases, the crystals changes into a bar shape as shown in FIG. 6. It is also observed that a thin film of a high concentration is formed without overall peeling or cracks.

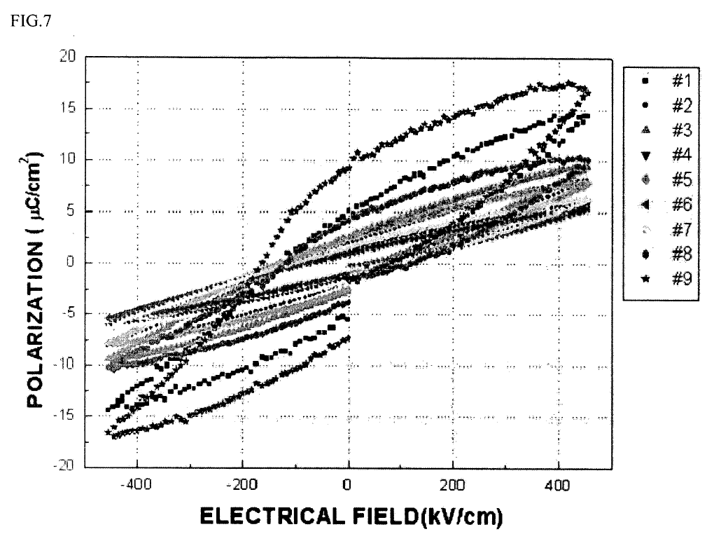

FIG. 7 shows an electric field-polarization curve for each sample. In FIG. 7, it is impossible to check electric features because electric short occurs in an area having much lanthanum. In particular, in case of a BLCT thin film with La/Ce=0.3/0.45, the residual polarization was 16.6 μC/cm² of the highest value.

TABLE 2
Electric field-polarization of thin film array of (Bi, La, Ce)₄Ti₃O₁₂
according to FIG. 7

| | Ce/La | Residual Polarization |
|---|---|---|
| Sample No. | (stoichiometric ratio) | (2Pᵣ) (μC/cm²) |
| #1 | 0.75/0 | 10.6 |
| #2 | 0.65/0.1 | 3.7 |
| #3 | 0.6/0.15 | 5.3 |
| #4 | 0.5/0.25 | 2.9 |
| #5 | 0.45/0.3 | 5.0 |
| #6 | 0.55/0.2 | 2.1 |
| #7 | 0.4/0.35 | 3.3 |
| #8 | 0.35/0.4 | 8.0 |
| #9 | 0.45/0.3 | 16.6 |

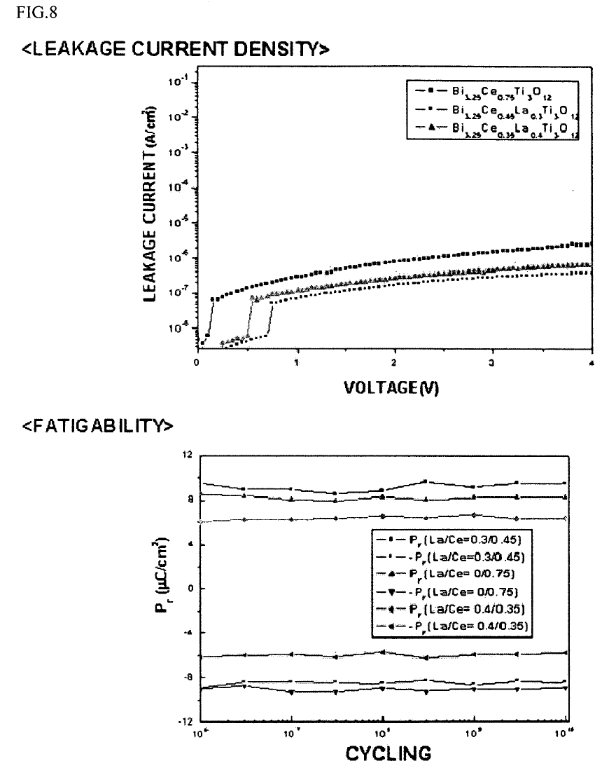

FIG. 8 shows the results of measurement for leakage current density and fatigability features for three samples that had large residual polarization.

With respect to fatigability, the residual polarization value almost did not change in spite of switching equal to or more than 109 without regard to compositions. The leakage current showed about 10⁻⁷A/cm² at 3V when La/Ce=0.3/0.45.

TABLE 3
Leakage current density of a thin film array of (Bi, La, Ce)₄Ti₃O₁₂
according to FIG. 8

| | | Residual | |
|---|---|---|---|
| Sample | Ce/La | Polarization (2Pᵣ) | Leakage Current |
| No. | (stoichiometric ratio) | (μC/cm²) | (A/cm²) at 3 V |
| #1 | 0.75/0 | 10.6 | 1.48 * 10⁻⁶ |
| #8 | 0.35/0.4 | 8.0 | 4.5 * 10⁻⁷ |
| #9 | 0.45/0.3 | 16.6 | 2.7 * 10⁻⁷ |

Embodiment 1-2: Producing a Thin Film Array of (Bi,La,Ce)₄Ti₃O₁₂ (BLCT) (II)

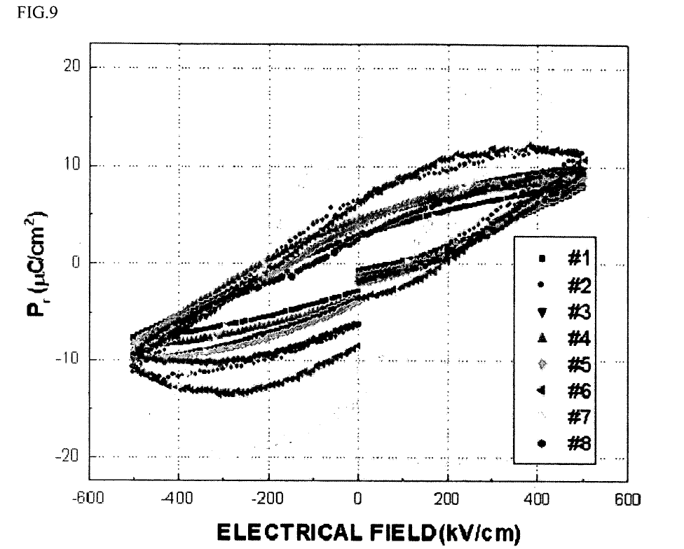

After producing two types of metal precursor liquid as for the embodiment 1-1, the thermal treatment process at 400° C. is not applied. However, for thermal treatment, the temperature is raised to 700° C. at the heating-up speed of 7° C. per minute from an ambient temperature and subsequent thermal treatment is then applied to the liquid at an oxygen atmosphere for 30 minutes. This is because it is intended to reduce volatilization of bismuth to a maximum and to observe electric features in all areas. Formation of a uniform phase is also observed through XRD in this case. FIG. 9 shows an electric field-polarization curve of this sample array obtained according to this embodiment 1-2.

TABLE 4
Electric field-polarization of a thin film array of
(Bi, La, Ce)₄Ti₃O₁₂
according to FIG. 9

| No. | Ce/La (stoichiometric ratio) | 2Pᵣ (μC/cm²) |
|---|---|---|
| 1 | 0.75/0 | 5.6 |
| 2 | 0.65/0.1 | 13.0 |
| 3 | 0.6/0.15 | 7.5 |
| 4 | 0.55/0.2 | 7.8 |
| 5 | 0.5/0.25 | 8.0 |
| 6 | 0.45/0.3 | 14.7 |
| 7 | 0.3/0.45 | 27.0 |
| 8 | 0.2/0.55 | 8.7 |

As shown in Table 4, it is seen that the overall residual polarization value is improved even better as compared to the embodiment 1-1. In particular, in the area where La/Ce=0.45/0.3, the residual polarization is very high as 27 μC/cm². As known in this test, assuming that one sample per experiment is produced as before, the deposition process must be carried out about 96 times (6 times per sample). However, by using only a shutter moving in the x-axis direction and a mask for specifying a deposited area as in the invention, it is possible to easily achieve optimized compositions only by four times of deposition.

Embodiment 2: Producing Cathode and Anode Catalyst Libraries of a Methanol Direct Decomposition Cell

For oxidization of methanol of the invention, total five types of metal precursor liquid of platinum, ruthenium, molybdenum, tungsten, gold precursors are produced. Arrays various in composition are then produced on carbon paper on which a mask is placed that had an area for deposition of droplets in the same process as in the aforementioned embodiment 1-1, to obtain a resultant library by chemical deoxidation with 0.5 M of NaBH₄ or deoxidation at a hydrogen atmosphere at 310□.

The above anode catalyst reacts methanol with water, the catalyst preferably consisting of 60 to 95 mol % of platinum and/or ruthenium and 5 to 40 mol % of at least two metals selected from a group comprising molybdenum, tungsten, gold, cobalt and nickel.

For the cathode reaction of oxygen, platinum, iron, selenium, ruthenium and molybdenum are used. For more detailed combinatorial detection related to the reaction, fluorescence detection proposed by Mallouk et. al. {T. E. Mallouk et. al. science, 280, 1735 (1998)} is applied.

The indicator used for detecting the anode is 300 micromols of quinine, and Phloxine B is used for detecting the cathode. The normal 3-electrode test is carried out, using the produced electrolyte and the array, and fluorescence detection is applied. The configuration of combinatory composition for the fluorescence-detected anode and cathode is shown in Tables 5 and 6.

TABLE 5
Composition of electrode library for methanol oxidation
In the order of Pt/Ru/Mo/W (unit of composition: mol %)

| | | | | | | | | | |
|---|---|---|---|---|---|---|---|---|---|
| 10/100/10/100 | 20/90/10/100 | 30/80/10/100 | 40/70/10/100 | 50/60/10/100 | 60/50/10/100 | 70/40/10/100 | 80/30/10/100 | 90/20/10/100 | 100/10/10/100 |
| 10/100/20/90 | 20/90/20/90 | 30/80/20/90 | 40/70/20/90 | 50/60/20/90 | 60/50/20/90 | 70/40/20/90 | 80/30/20/90 | 90/20/20/90 | 100/10/20/90 |
| 10/100/30/80 | 20/90/30/80 | 30/80/30/80 | 40/70/30/80 | 50/60/30/80 | 60/50/30/80 | 70/40/30/80 | 80/30/30/80 | 90/20/30/80 | 100/10/30/80 |
| 10/100/40/70 | 20/90/40/70 | 30/80/40/70 | 40/70/40/70 | 50/60/40/70 | 60/50/40/70 | 70/40/40/70 | 80/30/40/70 | 90/20/40/70 | 100/10/40/70 |
| 10/100/50/60 | 20/90/50/60 | 30/80/50/60 | 40/70/50/60 | 50/60/50/60 | 60/50/50/60 | 70/40/50/60 | 80/30/50/60 | 90/20/50/60 | 100/10/50/60 |
| 10/100/60/50 | 20/90/60/50 | 30/80/60/50 | 40/70/60/50 | 50/60/60/50 | 60/50/60/50 | 70/40/60/50 | 80/30/60/50 | 90/20/60/50 | 100/10/60/50 |
| 10/100/70/40 | 20/90/70/40 | 30/80/70/40 | 40/70/70/40 | 50/60/70/40 | 60/50/70/40 | 70/40/70/40 | 80/30/70/40 | 90/20/70/40 | 100/10/70/40 |
| 10/100/80/30 | 20/90/80/30 | 30/80/80/30 | 40/70/80/30 | 50/60/80/30 | 60/50/80/30 | 70/40/80/30 | 80/30/80/30 | 90/20/80/30 | 100/10/80/30 |
| 10/100/90/20 | 20/90/90/20 | 30/80/90/20 | 40/70/90/20 | 50/60/90/20 | 60/50/90/20 | 70/40/90/20 | 80/30/90/20 | 90/20/90/20 | 100/10/90/20 |
| 10/100/100/10 | 20/90/100/10 | 30/80/100/10 | 40/70/100/10 | 50/60/100/10 | 60/50/100/10 | 70/40/100/10 | 80/30/100/10 | 90/20/100/10 | 100/10/100/10 |

TABLE 6
Composition of library for oxygen cathode electrode
In the order of Pt/Ru/Fe/Se (unit of composition: mol %)

| | | | | | | | | | |
|---|---|---|---|---|---|---|---|---|---|
| 10/100/10/100 | 20/90/10/100 | 30/80/10/100 | 40/70/10/100 | 50/60/10/100 | 60/50/10/100 | 70/40/10/100 | 80/30/10/100 | 90/20/10/100 | 100/10/10/100 |
| 10/100/20/90 | 20/90/20/90 | 30/80/20/90 | 40/70/20/90 | 50/60/20/90 | 60/50/20/90 | 70/40/20/90 | 80/30/20/90 | 90/20/20/90 | 100/10/20/90 |
| 10/100/30/80 | 20/90/30/80 | 30/80/30/80 | 40/70/30/80 | 50/60/30/80 | 60/50/30/80 | 70/40/30/80 | 80/30/30/80 | 90/20/30/80 | 100/10/30/80 |
| 10/100/40/70 | 20/90/40/70 | 30/80/40/70 | 40/70/40/70 | 50/60/40/70 | 60/50/40/70 | 70/40/40/70 | 80/30/40/70 | 90/20/40/70 | 100/10/40/70 |
| 10/100/50/60 | 20/90/50/60 | 30/80/50/60 | 40/70/50/60 | 50/60/50/60 | 60/50/50/60 | 70/40/50/60 | 80/30/50/60 | 90/20/50/60 | 100/10/50/60 |
| 10/100/60/50 | 20/90/60/50 | 30/80/60/50 | 40/70/60/50 | 50/60/60/50 | 60/50/60/50 | 70/40/60/50 | 80/30/60/50 | 90/20/60/50 | 100/10/60/50 |
| 10/100/70/40 | 20/90/70/40 | 30/80/70/40 | 40/70/70/40 | 50/60/70/40 | 60/50/70/40 | 70/40/70/40 | 80/30/70/40 | 90/20/70/40 | 100/10/70/40 |
| 10/100/80/30 | 20/90/80/30 | 30/80/80/30 | 40/70/80/30 | 50/60/80/30 | 60/50/80/30 | 70/40/80/30 | 80/30/80/30 | 90/20/80/30 | 100/10/80/30 |
| 10/100/90/20 | 20/90/90/20 | 30/80/90/20 | 40/70/90/20 | 50/60/90/20 | 60/50/90/20 | 70/40/90/20 | 80/30/90/20 | 90/20/90/20 | 100/10/90/20 |
| 10/100/100/10 | 20/90/100/10 | 30/80/100/10 | 40/70/100/10 | 50/60/100/10 | 60/50/100/10 | 70/40/100/10 | 80/30/100/10 | 90/20/100/10 | 100/10/100/10 |

Embodiment 3: Producing Catalyst Libraries for Eliminating Nitrogen Oxide

It is not necessary to use a mask on which an area for deposition is predetermined, by using a reactor having 100 apertures (whose diameter is one mm) as a substrate in order to produce a catalyst library for eliminating nitrogen oxide. When producing the inventive library, zeolite is largely used as a carrier, and all of the ZSM-5 and 13X selected for zeolite is put into the apertures of the micro reactor. With precursors of platinum, copper, iron, cobalt, etc. as transition metals to be doped to the carrier thereafter, platinum chloride and copper nitrate, iron nitrate and cobalt nitrate are melt into water to produce four types of metal precursor liquid. In this case, the amount of platinum for doping is limited to a value equal to or less than 5 weight %, considering economical efficiency. With the four types of metal precursor liquid produced as described above, catalyst powder arrays doped differently in compositions, respectively, are produced by means of ion exchange using a shutter driven into the x-direction, that is a reaction between zeolite and transition metal precursors melt in water, as in the above embodiments. The powder arrays produced according to the above process are taken out from the vacuum chamber and then placed into a vacuum oven for 12 hours to dry them. Subsequently the arrays are baked at 500° C. for about four hours at an air atmosphere then to produce 100 powder arrays different in composition, respectively, as shown in Table 7. The number of samples can be increased to 1000 by increasing the number of the apertures.

TABLE 7
Composition of catalyst libraries for eliminating nitrogen oxide
In the order of Pt/Cu/Fe/Co (unit of composition: wt %)

| | | | | | | | | | |
|---|---|---|---|---|---|---|---|---|---|
| 0.5/10/1/10 | 1.0/9/1/10 | 1.5/8/1/10 | 2.0/7/1/10 | 2.5/6/1/10 | 3.0/5/1/10 | 3.5/4/1/10 | 4.0/3/1/10 | 4.5/2/1/10 | 5.0/1/1/10 |
| 0.5/10/2/9 | 1.0/9/2/9 | 1.5/8/2/9 | 2.0/7/2/9 | 2.5/6/2/9 | 3.0/5/2/9 | 3.5/4/2/9 | 4.0/3/2/9 | 4.5/2/2/9 | 5.0/1/2/9 |
| 0.5/10/3/8 | 1.0/9/3/8 | 1.5/8/3/8 | 2.0/7/3/8 | 2.5/6/3/8 | 3.0/5/3/8 | 3.5/4/3/8 | 4.0/3/3/8 | 4.5/2/3/8 | 5.0/1/3/8 |
| 0.5/10/4/7 | 1.0/9/4/7 | 1.5/8/4/7 | 2.0/7/4/7 | 2.5/6/4/7 | 3.0/5/4/7 | 3.5/4/4/7 | 4.0/3/4/7 | 4.5/2/4/7 | 5.0/1/4/7 |
| 0.5/10/5/6 | 1.0/9/5/6 | 1.5/8/5/6 | 2.0/7/5/6 | 2.5/6/5/6 | 3.0/5/5/6 | 3.5/4/5/6 | 4.0/3/5/6 | 4.5/2/5/6 | 5.0/1/5/6 |
| 0.5/10/6/5 | 1.0/9/6/5 | 1.5/8/6/5 | 2.0/7/6/5 | 2.5/6/6/5 | 3.0/5/6/5 | 3.5/4/6/5 | 4.0/3/6/5 | 4.5/2/6/5 | 5.0/1/6/5 |
| 0.5/10/7/4 | 1.0/9/7/4 | 1.5/8/7/4 | 2.0/7/7/4 | 2.5/6/7/4 | 3.0/5/7/4 | 3.5/4/7/4 | 4.0/3/7/4 | 4.5/2/7/4 | 5.0/1/7/4 |
| 0.5/10/8/3 | 1.0/9/8/3 | 1.5/8/8/3 | 2.0/7/8/3 | 2.5/6/8/3 | 3.0/5/8/3 | 3.5/4/8/3 | 4.0/3/8/3 | 4.5/2/8/3 | 5.0/1/8/3 |
| 0.5/10/9/2 | 1.0/9/9/2 | 1.5/8/9/2 | 2.0/7/9/2 | 2.5/6/9/2 | 3.0/5/9/2 | 3.5/4/9/2 | 4.0/3/9/2 | 4.5/2/9/2 | 5.0/1/9/2 |
| 0.5/10/10/1 | 1.0/9/10/1 | 1.5/8/10/1 | 2.0/7/10/1 | 2.5/6/10/1 | 3.0/5/10/1 | 3.5/4/10/1 | 4.0/3/10/1 | 4.5/2/10/1 | 5.0/1/10/1 |

Embodiment 4: Producing an Anodic Thin Film Library for Lithium Secondary Cell

The metal precursor liquid for producing LiCoO₂, LiNiO₂ and LiMnO₂ is melt into 2-methoxyethanol according to the stoichiometric ratio {lithium:transition metal (cobalt, nickel, manganese)=1.05:1}. In this case, lithium nitrate, cobalt nitrate, nickel nitrate and manganese nitrate are used as metal precursors, respectively. Considering the volatilization condition of lithium in the thermal treatment process in this case, the stoichiometric ratio is controlled to have an excess of 5%. A platinum wafer on which collectors for the anode and the cathode were patterned is used as a substrate. As the same in the previous process, the LiCoO₂ liquid is first put into the reactor to produce droplets, which are then transferred to a vacuum chamber at 700 torrs while achieving a concentration gradient by different deposition times for each location, using a shutter driven into the x-axis direction. Next, the liquid is replaced by LiMnO₂ liquid. The above process is then repeated but the shutter is driven into the direction opposite to the first direction. Subsequently, after rotating the substrate holder by 90°, the LiNiO₂ liquid is deposited while the shutter is driven. Then in the last step, the LiMnO₂ liquid is deposited again while the shutter is driven in the direction opposite to the above direction then to produce 16 anodic thin films different in composition. The anodic thin film produced as such is subject to subsequent thermal treatment for five minutes at 800° C. at an oxygen atmosphere in a fast thermal treatment apparatus. The composition of the thin film array produced according to the above process is shown in Table 8. In order to apply an electrochemical test to the array, about 1.5 μm of LIPON is deposited as an electrolyte by sputtering and a lithium electrode is then deposited finally. Since the lithium electrode is very sensitive to moisture, a pouch-shaped cell is produced in a glove box or a dry room without moisture and a charge and discharge test is applied to the array, using a charge and discharge apparatus having 16 channels. For the charge and discharge condition, the potential condition is 3 to 4.3V, the charge and discharge speed is 1 C and the test is repeated 100 times.

TABLE 8
Composition of anode library for lithium secondary cell
(where the composition is based on chemical molecular formulae.)

| | | | |
|---|---|---|---|
| LiCo_{0.5}Mn_{0.5}O₂ | LiCo_{0.33}Mn_{0.67}O₂ | LiMn_{0.83}Co_{0.17}O₂ | LiMnO₂ |
| LiCo_{0.5}Ni_{0.17}Mn_{0.33}O₂ | LiCo_{0.33}Ni_{0.17}Mn_{0.5}O₂ | LiCo_{0.17}Ni_{0.17}Mn_{0.66}O₂ | LiNi_{0.17}Mn_{0.83}O₂ |
| LiCo_{0.5}Ni_{0.33}Mn_{0.17}O₂ | LiCo_{0.33}Ni_{0.33}Mn_{0.33}O₂ | LiCo_{0.17}Ni_{0.33}Mn_{0.5}O₂ | LiNi_{0.33}Mn_{0.67}O₂ |
| LiCo_{0.5}Ni_{0.5}O₂ | LiCo_{0.33}Ni_{0.5}Mn_{0.17}O₂ | LiCo_{0.17}Ni_{0.5}Mn_{0.33}O₂ | LiNi_{0.5}Mn_{0.5}O₂ |

As described and proved in detail in the above, by means of a method of producing a thin film or powder array by the liquid source misted chemical deposition process according to the invention, it is possible to easily produce a thin film or powder array having various features of inorganic materials, e.g., ferroelectrics, and environment-friendly catalysts., e.g., catalysts for eliminating nitrogen oxide to implement methods of discovery and optimization of new materials by combinational chemistry. It is also possible to produce an array for combinational chemistry having a uniform phase by inter-liquid mixture at an ambient temperature and to make particles even finer in size for deposition, resulting in more improved features of materials. By the method according to the invention, it is possible to significantly reduce time and cost required for the prior art tests while producing and discovering multicomponent-system materials and catalysts.

From the foregoing description, it will be observed that various modifications and changes can be made without departing from the true sprit and scope of the present invention. It should be understood that the foregoing description is intended to illustrate and not to limit the scope of the invention as defined by the claims.

1. A method of producing a thin film or powder array by a liquid source misted chemical deposition process, characterized by comprising the steps of:
a first step of melting a metal precursor consisting of a material or catalyst into a solvent and producing two or more types of metal precursor liquid;
a second step of selecting one type of liquid from said two or more types of liquid, putting it into a reactor and producing droplets thereof by applying high frequency to the liquid;
a third step of transferring said droplets into a vacuum chamber, at a given pressure;
a fourth step of depositing said droplets on each area of a substrate to have a concentration gradient by means of a shutter or a moving mask;
a fifth step of producing a thin film or powder array with said droplets by thermal treatment process; and
a sixth step of repeating said steps 2 to 5 for different liquid selected from said two or more different types of liquid produced in said step 1.

2. Method as claimed in claim 1, characterized in that four types of droplets are produced in the first step, in that, when the four types of produced droplets are deposited on said substrate, respectively, second droplets are transferred into a direction opposite to the direction of driving the shutter for the first droplets, and in that third and fourth droplets are transferred into a direction or an opposite direction of driving the shutter on the area of the substrate rotated by 90°.

3. Method as claimed in claim 1, characterized in that said material and catalyst comprise inorganic materials, ionic solids, organic metal materials, metal alloys, complexes, and organic polymers.

4. Method as claimed in claim 1, characterized in that said metal precursors are one or more material selected from a group consisting of metal nitrate (—NO₃), acetate (—CH₃COO.2H₂O), carbonate (—CO₃), acetylacetonate (—CH₃COCHCOCH₃), 2-ethylhexanoate (—OOCCH(C₂H₅)C₄H₉), stearate ((O₂C₁₈H₃₅)₂) and alkoxide (—(OR)n, R=alkyl radical).

5. Method as claimed in claim 1, characterized in that a deposition thickness of said thin film or powder array is 0.1 μm to 1 μm.

6. Method as claimed in claim 1, characterized in that said substrate is either a wafer made of tungsten, molybdenum, gold, aluminum, copper, platinum, silicon, or silicon oxide, or a reactor having 100 or more apertures made by photolithography.

7. Method as claimed in claim 1, characterized in that deposition and production of said thin film or powder array is carried out at a pressure ranging from 10⁻⁶ to 760 torrs.

8. Method as claimed in claim 1, characterized in that for deposition and production of said thin film or powder array, a gas such as oxygen, nitrogen, argon or helium is used for the condition of implementing a production atmosphere, in order to achieve efficient reaction between liquids and mixture thereof.

9. Method as claimed in claim 1, characterized in that said solvent for dissolving said metal precursors is an organic solvent containing one to ten carbons including methanol, ethanol, propanol, isopropanol, butanol, 2-methoxyethanol, toluene, benzene, phenol, 2-ethylhexanoate, acetone and acetylacetonate, or polar solvents such as water.

10. Method as claimed in claim 1, characterized in that for said thermal process, a furnace or a fast thermal treatment apparatus can be used, and a gas, e.g., oxygen, nitrogen, hydrogen, argon or helium at 50 to 1500° C. is used.

11. Method as claimed in claim 2, characterized in that said material and catalyst comprise inorganic materials, ionic solids, organic metal materials, metal alloys, complexes, and organic polymers.

12. Method as claimed in claim 2, characterized in that said metal precursors are one or more material selected from a group consisting of metal nitrate (—NO₃), acetate (—CH₃COO.2H₂O), carbonate (—CO₃), acetylacetonate (—CH₃COCHCOCH₃), 2-ethylhexanoate (—OOCCH(C₂H₅)C₄H₉), stearate ((O₂C₁₈H₃₅)₂) and alkoxide (—(OR)n, R=alkyl radical).

13. Method as claimed in claim 2, characterized in that a deposition thickness of said thin film or powder array is 0.1 μm to 1 μm.

14. Method as claimed in claim 2, characterized in that said substrate is either a wafer made of tungsten, molybdenum, gold, aluminum, copper, platinum, silicon, or silicon oxide, or a reactor having 100 or more apertures made by photolithography.

15. Method as claimed in claim 2, characterized in that deposition and production of said thin film or powder array is carried out at a pressure ranging from 10⁻⁶ to 760 torrs.

16. Method as claimed in claim 2, characterized in that for deposition and production of said thin film or powder array, a gas such as oxygen, nitrogen, argon or helium is used for the condition of implementing a production atmosphere, in order to achieve efficient reaction between liquids and mixture thereof.

17. Method as claimed in claim 2, characterized in that said solvent for dissolving said metal precursors is an organic solvent containing one to ten carbons including methanol, ethanol, propanol, isopropanol, butanol, 2-methoxyethanol, toluene, benzene, phenol, 2-ethylhexanoate, acetone and acetylacetonate, or polar solvents such as water.

18. Method as claimed in claim 2, characterized in that for said thermal process, a furnace or a fast thermal treatment apparatus can be used, and a gas, e.g., oxygen, nitrogen, hydrogen, argon or helium at 50 to 1500° C. is used.
